(19) United States
(12) Patent Application Publication
(10) Pub. No.: US 2013/0185898 A1
(43) Pub. Date: Jul. 25, 2013

(54) HINGE STRUCTURE FOR ASSEMBLY OF A DISPLAY MODULE

(71) Applicants: Ting-Hung SU, New Taipei City (TW); Wen Yan Lin, New Taipei City (TW)

(72) Inventors: Ting-Hung SU, New Taipei City (TW); Wen Yan Lin, New Taipei City (TW)

(21) Appl. No.: 13/355,998

(22) Filed: Jan. 23, 2012

(51) Int. Cl. H05K 7/00; E05D 11/00

(52) U.S. Cl. 16/250; 16/380

(57) ABSTRACT

A hinge structure for assembly of a display module is located on a base. The hinge structure includes a first holder and a second holder. The first holder includes an assembly portion and at least one pin coupled with the assembly portion. The second holder includes a hinge portion hinged on the pin and a connecting portion fastened to a host of a notebook computer. The display module is located in a first holding groove and a second holding groove of the assembly portion, thereby the hinge structure and display module are fastened together to reduce thickness caused by front fastening to achieve the object of thin and light panel design. By direct coupling of the display module and the assembly portion the extra production process of fastening the hinge to the display module can be dispensed with to simplify production.

### FIELD OF THE INVENTION

The present invention relates to a hinge structure and particularly to a hinge structure for assembly of a display module.

### BACKGROUND OF THE INVENTION

Earlier CCFL (Cold Cathode Fluorescent Lamp) consists of a backlight module (cold cathode ray tube) and a liquid crystal light interrupter. The liquid crystal light interrupter consists of a polarizer, a glass substrate, a transparent electrode and a liquid crystal layer. As a result, the CCFL panel has a substantial thickness. In the past fastening the CCFL panel relies on two side legs to hold the liquid crystal screen. The lateral sides of the liquid crystal panel are fastened to the side legs, then are hinged on the host of a notebook computer. To meet the requirements of long use time of the notebook computer and thin and light product design, the earlier CCFL panel is gradually being replaced by LED panel. However, the lateral sides of the LED panel usually do not have a sufficient thickness for fastening of the side legs. Hence the LED panel generally is fastened on the front side that results in a greater thickness of the LED display.

To overcome the aforesaid problem, Taiwan patent M365626 discloses a hinge fastening structure for thin display panels. It includes a wedge coupling plate on each of two sides of the panel, and a rack with a holding portion and a plurality of elastic reeds to elastically clamp the wedge coupling plate so that the LED panel is clamped and held elastically without increasing thickness caused by the front fastening. But such a fastening approach makes production process more difficult, and a front lid and a rear lid are required to encase the hinge fastening structure and electric circuitry. As a result, the thickness of the liquid crystal screen is still quite significant and cannot fully meet the thin and light requirement of the display panel of notebook computers.

### SUMMARY OF THE INVENTION

The primary object of the present invention is to solve the problems of the conventional LED panel that is too thin and can be fastened only at the front side or via elastic clamping and results increasing of thickness, and the older LED panel that needs a front lid and a rear lid and results in occupying too much space.

To achieve the foregoing object the present invention provides a hinge structure for assembly of a display module. It is located on a base. The display module includes at least a first optical film and a second optical film. The hinge structure includes a first holder and a second holder. The first holder includes an assembly portion and at least one pin coupled with the assembly portion. The assembly portion includes a first holding groove to hold the first optical film and a second holding groove to hold the second optical film. The first and second holding grooves are parallel with each other. The second holder includes a hinge portion hinged by the pin and a connecting portion fastened to the base.

In one embodiment the first optical film includes a backlight module.

In another embodiment the second optical film includes a liquid crystal light interrupter.

In yet another embodiment the assembly portion includes a third holding groove to couple with a third optical film.

In yet another embodiment the third holding groove is formed at a depth between 0.5 and 1.0 mm.

In yet another embodiment the third optical film is a polarizer.

In yet another embodiment the assembly portion includes two parallel extension racks, a top rack located between the two extension racks and a bottom rack located between the two extension racks and coupled with the pin.

In yet another embodiment the top rack includes a retaining groove to hold a video device.

In yet another embodiment the top rack has two ends connecting to the two extension racks in an integrated manner.

In yet another embodiment the bottom rack includes a pin sleeve insertable by the pin, a sleeve holder coupled on the pin sleeve, a first holding portion located on the sleeve holder to mate the extension racks, and each extension rack has a second holding portion at one end fastening to the first holding portion.

In yet another embodiment the each extension rack includes a first coupling portion at one end, and the pin sleeve has a second coupling portion at one end coupled with the first coupling portion, a leaning portion at another end opposite to the second coupling portion to butt the sleeve holder, and a fastening element running through and fastening the first coupling portion and second coupling portion to make the leaning portion to press tightly the sleeve holder and extension rack.

In yet another embodiment the pin has an axial aperture run through by a power wire, and the pin sleeve has a wiring groove communicating with the aperture to be threaded through by the power wire.

In yet another embodiment the bottom rack includes at least one wire passing groove communicating with the wiring groove and a first guide trough communicating with the wire passing groove to guide the wire to be deployed along the extension direction.

In yet another embodiment the extension rack has a second guide trough to guide the wire to pass through the bottom rack and to be deployed along the extension direction.

In yet another embodiment the top rack includes a third guide trough formed in the extension direction thereof to communicate with the second guide trough.

In yet another embodiment the first holding groove is formed at a depth ranged from 0.5 to 0.81 nm.

In yet another embodiment the second holding groove is formed at a depth ranged from 0.2 to 0.5 mm.

On the hinge structure thus formed, the assembly portion has a plurality of holding grooves overlapped in a parallel manner to hold multiple optical films or a cover plate, and the first holder and the second holder becomes a frame of the display module. Compared with the conventional techniques, the hinge structure not only saves the space required by the front fastening, and also saves the space occupied by the cover plate. Through the overlapped structure, the complexity of assembling the display module via operators or robotic arms is eliminated. The hinge structure of the invention not only is lighter and thinner, but also simplifies the fabrication process and reduces the cost.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of a first embodiment of the invention.

FIG. 2 is an exploded view of the first embodiment of the invention.

FIG. 3 is a schematic view of the first embodiment of the invention showing the holding grooves and optical films in a coupled condition.

FIG. 4 is a schematic view of the first embodiment of the invention showing a wiring layout of conductive wires.

FIG. 5 is a perspective view of a second embodiment of the invention.

FIG. 6 is an exploded view of the second embodiment of the invention.

FIG. 7 is a fragmentary exploded view of the second embodiment of the invention.

FIG. 8 is schematic view of the second embodiment of the invention showing a wiring layout of the conductive wires

### DETAILED DESCRIPTION OF THE PREFERRED EMBODIMENTS

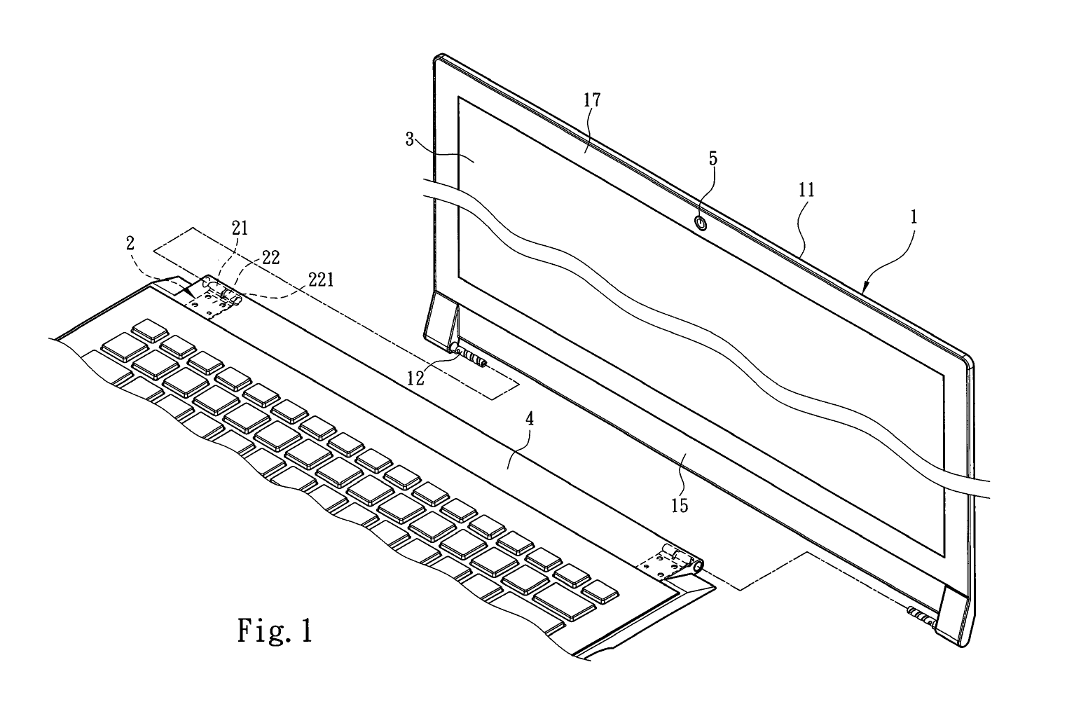

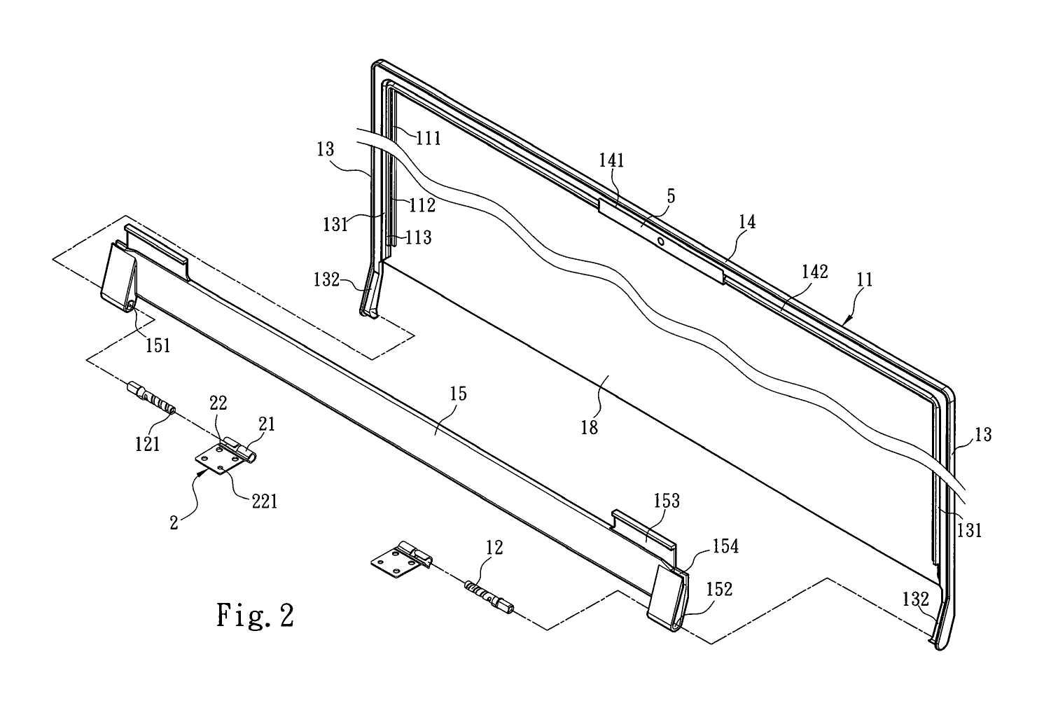

Please referring to FIGS. 1 and 2, the present invention aims to provide a hinge structure for assembly of a display module. It is located on a base 4. In this embodiment, the base 4 is a host of a notebook computer that can include an electronic device (not shown in the drawings) consisting of a processing unit, a keyboard module, a storage device, a wireless terminal module or an optical read/write device and the like. The hinge structure for assembly of a display module includes a first holder 1 and a second holder 2. The first holder 1 includes an assembly portion 11 and at least one pin 12 coupled with the assembly portion 11. The assembly portion 11 has two parallel extension racks 13 coupled with the pin 12, a top rack 14 located between the two extension racks 13 and a bottom rack 15. The top rack 14 includes a retaining groove 141 to hold a video device 5 and two ends fastened integrally to the two extension racks 13. The bottom rack 15 has two fastening portions 151 insertable by the pin 12 and a second holding portion 152 at two ends thereof. The two extension racks 13 have respectively a first holding portion 132 corresponding and fastening to the second holding portion 152, thereby the bottom rack 15 and two extension racks 13 can be held together. The bottom rack 15 also has a wiring groove 154 communicating with the fastening portion 151 and an axial aperture 121 of the pin 12. The second holder 2 is connected to the base 4, and includes a connecting portion 22 fastened to the base 4 and a hinge portion 21 hinged on the pin 12 so that the first holder 1 can be swiveled against the second holder 2 at an inclined angle. The connecting portion 22 has four fastening holes 221 formed thereon.

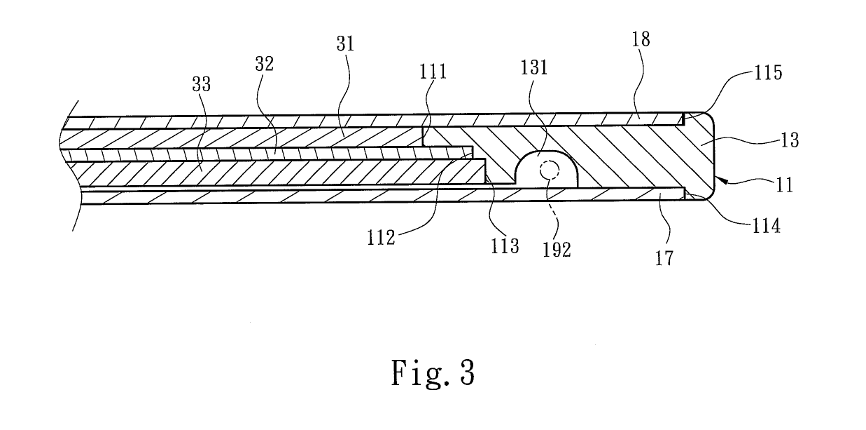

Referring to FIG. 3, the assembly portion 11 includes, at varying depths between the two extension racks 13 and top rack 14, a first holding groove 111 to hold a first optical film 31, a second holding groove 112 to hold a second optical film 32 and a third holding groove 113 to hold a third optical film 33. The top rack 14, bottom rack 15 and two extension racks 13 also surround to form an indented front holding recess 114 and an indented rear holding recess 115. The front holding recess 114 holds a front lid 17, and the rear holding recess 115 holds a rear lid 18. The front and rear lids 17 and 18 are made of material same as the assembly portion 11 to enhance visual integration sense of products, or reinforced glass to improve impact resistant capability of the display module 3, or may be a touch panel to receive input commands to interact with the host. The first optical film 31 can be a backlight module such as a LED lateral backlight module, a CCFL lateral backlight module or a CCFL direct backlight module. The second optical film 32 can be a liquid crystal light interrupter, such as TFT-LCD (Thin film transistor liquid crystal display), TN (Twisted Nematic), PVA (Pattern Vertical Alignment) and S-PVA (Super Pattern Vertical Alignment), S-IPS (Super-In Plane Switching), P-MVA (Premium Multidomain Vertical Alignment) and S-MVA (Super Multidomain Vertical Alignment). The third optical film 33 can be a polarizer.

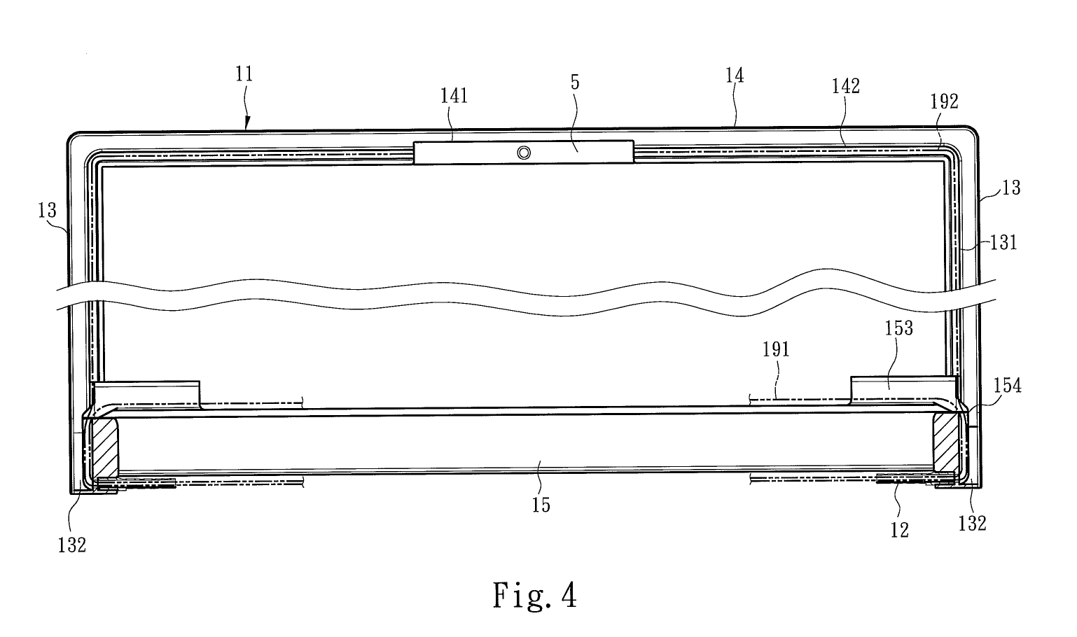

Please referring to FIG. 4, each extension rack has a second guide trough 131 which is extended towards the top rack 14 to communicate with a third guide trough 142 formed on the top rack 14. The bottom rack 15 has two wiring grooves 154 to hold a wire and a first guide trough 153 in the extension direction thereof to communicate with the wiring groove 154.

Also referring to FIG. 4, in this embodiment, a first conductive wire 191 and a second conductive wire 192 are provided to pass trough the aperture 121 of the pin 12, wiring grooves 154 of the bottom rack 15, second guide trough 131 of the extension racks 13, first guide trough 153 of the bottom rack 15 and third guide trough 142 of the top rack 14 to connect various devices on the assembly portion 11, such as the display module 3 and video device 5 and the like.

Also referring to FIGS. 2, 3 and 4, the fabrication process of the invention is performed in the sequence as follow: first, fasten the rear lid 18 by adhesive bonding to the rear holding recess 115 at another end in the user's visual direction as a holding base; start mounting sequentially the first optical film 31 on the first holding groove 111, the second optical film 32 on the second holding groove 112 and the third optical film 33 on the third holding groove 113; then start wiring process, thread the first conductive wire 191, in this order, through the aperture 121 of the pin 12, wiring groove 154 and first guide trough 153 of the bottom rack 15 to the first, second and third optical films 31, 32 and 33 to form electric connection therewith. Thereby, as shown in FIG. 1, the base 4 can output data via the first conductive wire 191 to the display module 3. The second conductive wire 192 is threaded, first, through the aperture 121 of the pin 12, then through the wiring groove 154 of the bottom rack 15 into the second guide trough 131 of the first extension rack 13, and finally through the third guide trough 142 of the top rack 14 to the retaining groove 141 of the top rack 14 to form electric connection with the video device 5, and through the second conductive wire 192 to send the data processed by the video device 5 to the electronic device (not shown in the drawings) on the base 4; finally, mount the front lid 17 onto the front holding recess 114 to form a compact structure with the assembly portion 11 to encase the first optical film 31, second optical film 32, third optical film 33, first conductive wire 191 and second conductive wire 192 inside.

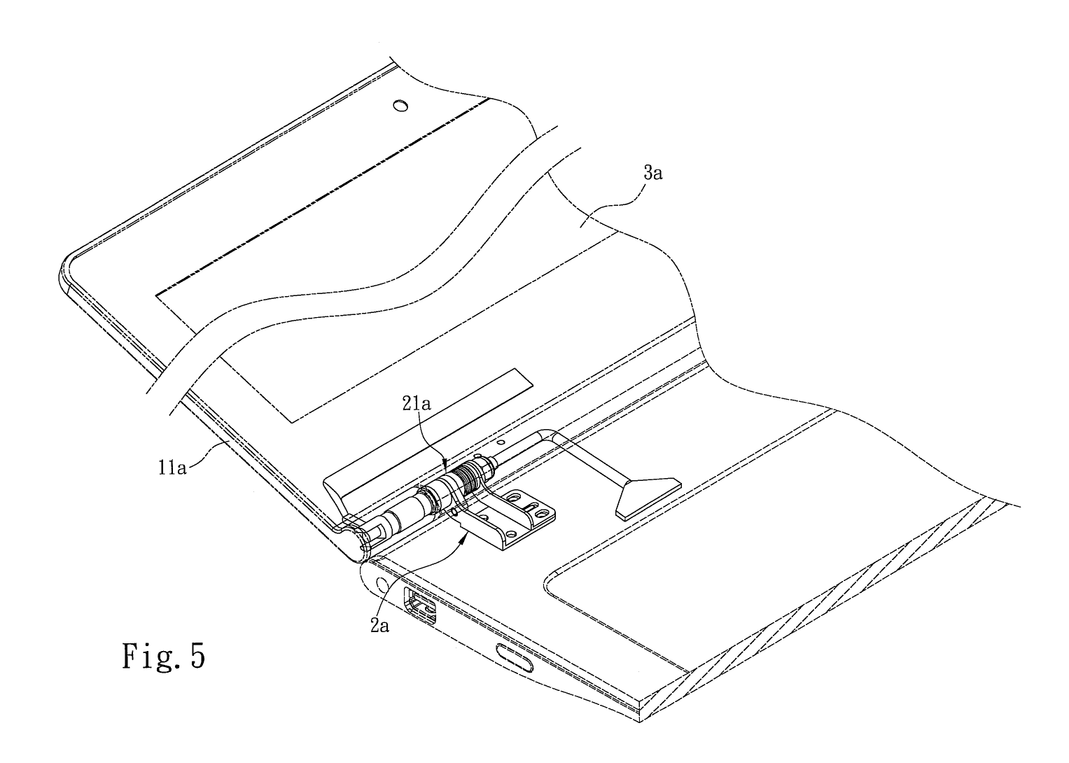

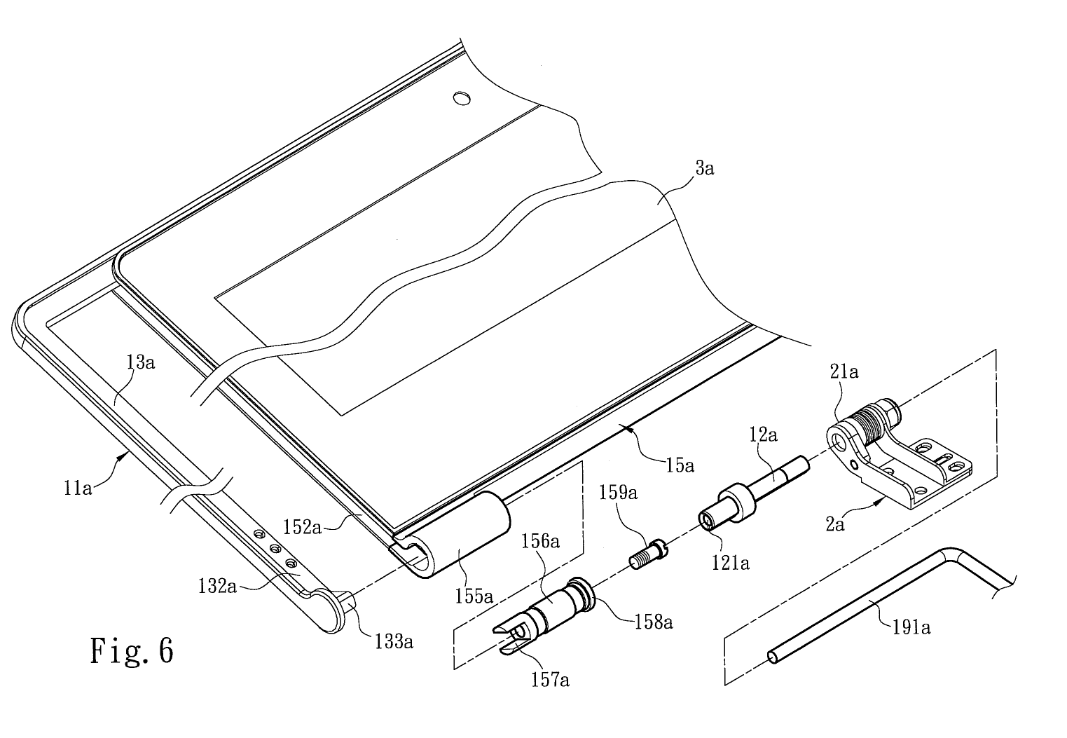

Please refer to FIGS. 5 and 6 for a second embodiment of the invention. It includes a bottom rack 15a with a pin sleeve 156a insertable by a pin 12a, a sleeve holder 155a to hold the pin sleeve 156a and a second holding portion 152a located on the sleeve holder 155a mating the extension rack 13a. The extension rack 13a has a first holding portion 132a coupled with the second holding portion 152a, thereby to hold the extension rack 13a and bottom rack 15a together. On the other hand, the extension rack 13a has a first coupling portion 133a at one end, and the pin sleeve 156a has a second coupling portion 157a at one end coupled with the first coupling portion 133a, a leaning portion 158a at another end opposite to the second coupling portion 157a to butt the sleeve holder 155a, and a fastening element 159a running through and fastening the first coupling portion 133a and second coupling portion 157a to make the leaning portion 158a and extension racks 13a to press tightly the sleeve holder 155a from two sides thereof, thereby the bottom rack 15a is tightly coupled on the two extension racks 13a.

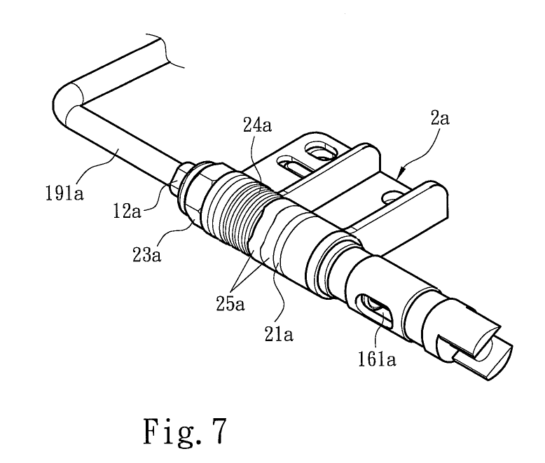

Referring to FIG. 7, the hinge structure of the invention also provides elastic return function. The pin 12a, incorporating with the hinge portion 21a of the second holder 2a, is coupled in series with two anchor plates 25a that can be anchored via the corresponding structure, a plurality of elastic washers 24a coupled on the pin 12a and pressed by the anchor plates 25a during swiveling thereof, and an end sealing member 23a to tightly press the anchor plates 25a and elastic washers 24a. Thereby, when the pin 12a drives the anchor plates 25a swiveling, the convex spots (not shown in the drawings) press against each other to increase the width between them and compress the elastic washers 24a to store elastic potential energy. When released, the elastic washers 24a release the elastic potential energy to force the anchor plates 25a to return in a concave spots mating the convex spots condition to achieve elastic return effect.

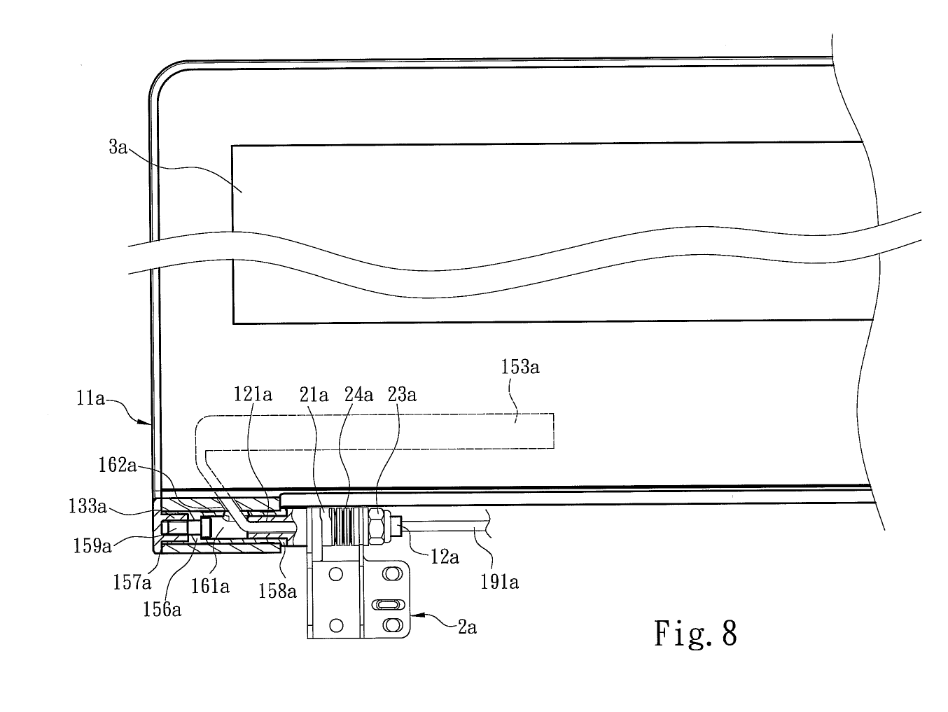

Referring to FIG. 8, the bottom rack 15a (also referring to FIG. 6) includes a wire passing trough 162a. The pin sleeve 156a has a threading trough 161a corresponding to the wire passing trough 162a to be threaded through by the first conductive wire 191a located at the bottom rack 15a. In this embodiment, the wire threading route is as follow: the first conductive wire 191a threads through the aperture 121a of the pin 12a, threading trough 161a of the pin sleeve 156a, wire passing trough 162a of the bottom rack 15a and first guide trough 153a of the bottom rack 15a, then is connected to the display module 3a installed on the assembly portion 11a.

Thus, the hinge structure of the invention provides the assembly portion as a frame of the display module, front lid and rear lid to form an overlapped stacking for them, thereby can save the space previously occupied by the front lid and rear lid fastened to the display module. Compared with the conventional techniques of providing two racks at two sides of the LCD to hold the panel that occupy a lot of space by the front and rear panels, the structure of present invention is thinner and lighter and offers greater portability. It also does not need the extra process for front fastening or setting racks to hold the LCD like the conventional techniques, hence can greatly reduce production complexity and improve production efficiency, and better meet market requirements.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A hinge structure for assembly of a display module, which is located on a base, the assembly of a display having at least a first optical film and a second optical film, comprising:
a first holder including an assembly portion and at least one pin coupled on the assembly portion, the assembly portion including a first holding groove to hold the first optical film and a second holding groove to hold the second optical film, the first holding groove and the second holding groove being parallel with each other; and
a second holder including a hinge portion hinged on the pin and a connecting portion fastened to the base.

2. The hinge structure of claim 1, wherein the first optical film includes a backlight module.

3. The hinge structure of claim 1, wherein the second optical film includes a liquid crystal light interrupter.

4. The hinge structure of claim 1, wherein the assembly portion includes a third holding groove to couple with a third optical film.

5. The hinge structure of claim 4, wherein the third holding groove is formed at a depth ranged from 0.5 mm to 1.0 mm.

6. The hinge structure of claim 4, wherein the third optical film is a polarizer.

7. The hinge structure of claim 1, wherein the assembly portion includes two parallel extension racks, a top rack located between the two extension racks and a bottom rack located between the two extension racks and coupled with the pin.

8. The hinge structure of claim 7, wherein the top rack includes a retaining groove to hold a video device.

9. The hinge structure of claim 7, wherein the top rack includes two ends fastened integrally to the two extension racks.

10. The hinge structure of claim 7, wherein the bottom rack includes a pin sleeve insertable by the pin, a sleeve holder coupled on the pin sleeve and a second holding portion located on the sleeve holder corresponding to the extension racks, each extension rack including a first holding portion at one end thereof to fasten to the second holding portion.

11. The hinge structure of claim 10, wherein each extension rack includes a first coupling portion at one end, the pin sleeve including a second coupling portion at one end thereof coupled with the first coupling portion, a leaning portion at another end opposite to the second coupling portion to butt the sleeve holder and a fastening element to run through and fasten the first coupling portion and the second coupling portion so that the leaning portion tightly presses the sleeve holder and the extension rack.

12. The hinge structure of claim 10, wherein the pin includes an axial aperture threaded through by a power wire, the pin sleeve including a wiring groove communicating with the aperture and threaded trough by the power wire.

13. The hinge structure of claim 12, wherein the bottom rack include at least one wire passing groove communicating with the wiring groove and a first guide trough communicating with the wire passing groove to guide the wire to travel in the extended direction of the bottom rack.

14. The hinge structure of claim 7, wherein each extension rack includes a second guide trough to guide the wire to pass through the bottom rack and travel in the extended direction of the extension rack.

15. The hinge structure of claim 14, wherein the top rack includes a third guide trough in the extended direction of the top rack to communicate with the second guide trough.

16. The hinge structure of claim 1, wherein the first holding groove is formed at a depth ranged from 0.5 mm to 0.8 mm.

17. The hinge structure of claim 1, wherein the second holding groove is formed at a depth ranged from 0.2 mm to 0.5 mm.
